(19) United States
(12) Patent Application Publication
(10) Pub. No.: US 2014/0239422 A1
(43) Pub. Date: Aug. 28, 2014

(54) ELECTRONIC DEVICE, PACKAGE, ELECTRONIC APPARATUS, AND MOVING OBJECT

(71) Applicant: Seiko Epson Corporation, Tokyo (JP)

(72) Inventor: Shinya AOKI, Minowa (JP)

(73) Assignee: Seiko Epson Corporation, Tokyo (JP)

(21) Appl. No.: 14/182,609

(22) Filed: Feb. 18, 2014

(30) Foreign Application Priority Data
Feb. 22, 2013 (JP) 2013-032941

(51) Int. Cl. H01L 41/02; H01L 23/48

(52) U.S. Cl. CPC H01L 41/02; H01L 23/48
USPC 257/415; 257/773

(57) ABSTRACT

A physical quantity sensor includes an IC chip and a package base mounted with the IC chip. The package base includes a first wiring layer provided with bonding pads connected to the IC chip via a bonding wire, a second wiring layer overlapping the first wiring layer in plan view, and an insulating layer provided between the first wiring layer and the second wiring layer. A contour of a wiring pattern provided on the second wiring layer (of the second wiring layer) is arranged in a position not overlapping the bonding pads in plan view.

### BACKGROUND

1. Technical Field

The present invention relates to an electronic device and to an electronic apparatus and a moving object including the electronic device.

2. Related Art

As an example of an electronic device, there has been known a piezoelectric oscillator. In the piezoelectric oscillator, a piezoelectric transducer is laminated on the upper surface of a ceramic container including an IC (integrated circuit) for oscillating circuit arranged in a recess formed on the upper surface thereof. A terminal for performing electrical connection to the IC for oscillating circuit by a bonding wire is provided on the bottom surface in the recess of the ceramic container. When the terminal is connected to terminals for transducer connection of the IC for oscillating circuit, the terminals can change the connection without crossing one another (see, for example, JP-A-2006-114976 (Patent Literature 1).

In an embodiment in Patent Literature 1, in the piezoelectric oscillator, some of the terminals for performing electrical connection to the IC for oscillating circuit by the bonding wire provided on the bottom surface in the recess of the ceramic container formed by a ceramic laminated plate overlap a contour of an electrode pattern on a lower layer (a layer right under the terminals) in plan view.

Consequently, in the piezoelectric oscillator, a layer of ceramic is partially raised by the thickness of the electrode pattern on the lower layer. Therefore, in the terminals provided on the bottom surface in the recess of the ceramic laminated plate, a level difference sometimes occurs between a portion overlapping the electrode pattern on the lower layer and a portion not overlapping the electrode pattern on the lower layer.

As a result, in the piezoelectric oscillator (an electronic device), flatness of the terminals (bonding pads) is spoiled. Therefore, it is likely that wire bondability of the terminals is deteriorated and reliability of mechanical and electrical connection to the IC for oscillating circuit (an electronic element) by the bonding wire decreases.

### SUMMARY

An advantage of some aspects of the invention is to solve at least a part of the problems described above, and the invention can be implemented as the following forms and application examples.

### Application Example 1

An electronic device according to this application example includes: an electronic element; and a laminated substrate mounted with the electronic element. The laminated substrate includes: a first wiring layer provided with at least one bonding pad connected to the electronic element via a bonding wire; a second wiring layer overlapping the first wiring layer in plan view; and an insulating layer provided between the first wiring layer and the second wiring layer. A contour of the second wiring layer is arranged in a position not overlapping the bonding pad in plan view.

According to this application example, in the electronic device, the contour of the second wiring layer is arranged in the position not overlapping the bonding pad of the first wiring layer in plan view. Therefore, a level difference due to the thickness of the second wiring layer does not occur in the bonding pad.

Consequently, in the electronic device, flatness of the bonding pad is secured. Therefore, wire bondability of the bonding wire to the bonding pad (hereinafter simply referred to as bondability) is improved. It is possible to surely connect (fix) the bonding wire to the bonding pad.

As a result, the electronic device can improve reliability of mechanical and electrical connection of the electronic element and the bonding pad by the bonding wire.

### Application Example 2

In the electronic device according to the application example described above, it is preferable that at least a plurality of the bonding pads are provided, and a part of the contour of the second wiring layer is arranged substantially in the middle between the bonding pads adjacent to each other in plan view.

According to this application example, in the electronic device, a part of the contour of the second wiring layer is arranged substantially in the middle between the bonding pads adjacent to each other in plan view. Therefore, even if fluctuation in positions occurs, the bonding pads on both sides of the contour less easily overlap the contour of the second wiring layer and the level difference less easily occurs.

Consequently, the electronic device can improve the bondability of the bonding wire to the bonding pad while expanding a tolerance of fluctuation in a manufacturing process for the laminated substrate (e.g., deviation of laminating positions of layers and deviation of forming positions of the bonding pad and the wiring pattern).

### Application Example 3

In the electronic device according to the application example described above, it is preferable that the insulating layer includes a ceramic material.

According to this application example, in the electronic device, the insulating layer includes the ceramic (ceramics) material. Therefore, the electronic device is excellent in insulation properties between the first wiring layer and the second wiring layer. A laminated state of the insulating layer before baking is clayish and soft.

Consequently, in the electronic device, the insulating layer is partially raised by the thickness of the second wiring layer of the laminated substrate and a level difference tends to occur in the first wiring layer. Therefore, it is possible to more markedly achieve the effect (the improvement of the bondability by the securing of the flatness of the bonding pad).

### Application Example 4

In the electronic device according to the application example described above, it is preferable that the electronic element is an IC chip.

According to this application example, in the electronic device, the electronic element is the IC chip. Therefore, reliability of mechanical and electrical connection of the IC chip and the bonding pad is improved. It is possible to surely actuate the IC chip that could have various functions.

### Application Example 5

In the electronic device according to the application example described above, it is preferable that the electronic device further includes a sensor element configured to detect a physical quantity, and the sensor element and the IC chip are electrically connected and function as a physical quantity sensor.

According to this application example, the electronic device includes the sensor element configured to detect a physical quantity, and the sensor element and the IC chip are electrically connected and function as the physical quantity sensor. Therefore, it is possible to provide the physical quantity sensor excellent in reliability.

### Application Example 6

In the electronic device according to the application example described above, it is preferable that all of the bonding pads provided on the first wiring layer are arranged in positions not overlapping the contour of the second wiring layer in plan view.

### Application Example 7

A package according to this application example includes: a first wiring layer provided with at least one bonding pad; a second wiring layer overlapping the first wiring layer in plan view; and an insulating layer provided between the first wiring layer and the second wiring layer. A contour of the second wiring layer is arranged in a position not overlapping the bonding pad in plan view.

### Application Example 8

In the package according to the application example described above, it is preferable that at least a plurality of the bonding pads are provided, and a part of the contour of the second wiring layer is arranged substantially in the middle between the bonding pads adjacent to each other in plan view.

### Application Example 9

In the package according to the application example described above, it is preferable that the insulating layer includes a ceramic material.

### Application Example 10

In the package according to the application example described above, it is preferable that all of the bonding pads provided on the first wiring layer are arranged in positions not overlapping the contour of the second wiring layer in plan view.

### Application Example 11

An electronic apparatus according to this application example includes the electronic device according to any one of the application examples explained above.

According to this application example, the electronic apparatus includes the electronic device according to any one of the application examples described above. Therefore, it is possible to provide the electronic apparatus excellent in reliability that reflects the effects of the application examples.

### Application Example 12

A moving object according to this application example includes the electronic device according to any one of the application examples described above.

### Application Example 13

An electronic apparatus according to this application example includes the package according to any one of the application examples described above.

### Application Example 14

A moving object according to this application example includes the package according to any one of the application examples described above.

According to this application example, the moving object includes the electronic device or the package according to any one of the application examples explained above. Therefore, it is possible to provide the moving object excellent in reliability that reflects the effects of the application examples.

### BRIEF DESCRIPTION OF THE DRAWINGS

The invention will be described with reference to the accompanying drawings, wherein like numbers reference like elements.

FIGS. 1A to 1C are schematic plan sectional views showing the schematic configuration of a physical quantity sensor in a first embodiment, wherein FIG. 1A is a schematic plan view of the physical quantity sensor overlooked from a lid side, FIG. 1B is a schematic sectional view taken along line A-A in FIG. 1A, and FIG. 1C is a schematic sectional view taken along line B-B in FIG. 1A.

FIGS. 2A and 2B are main part enlarged schematic diagrams of FIGS. 1A to 1C, wherein FIG. 2A is a schematic plan view and FIG. 2B is a schematic sectional view taken along line C-C in FIG. 2A.

FIGS. 3A and 3B are schematic diagrams showing the configuration of a main part of the physical quantity sensor applied with the configuration in the past, wherein FIG. 3A is a schematic plan view and FIG. 3B is a schematic sectional view taken along line C-C in FIG. 3A.

FIG. 4 is a perspective view showing a cellular phone as an example of an electronic apparatus in a second embodiment.

FIG. 5 is a schematic perspective view showing an automobile as an example of a moving object in a third embodiment.

### DESCRIPTION OF EXEMPLARY EMBODIMENTS

Embodiments embodying the invention are explained below with reference to the drawings.

### First Embodiment

First, a physical quantity sensor as an example of an electronic device is explained.

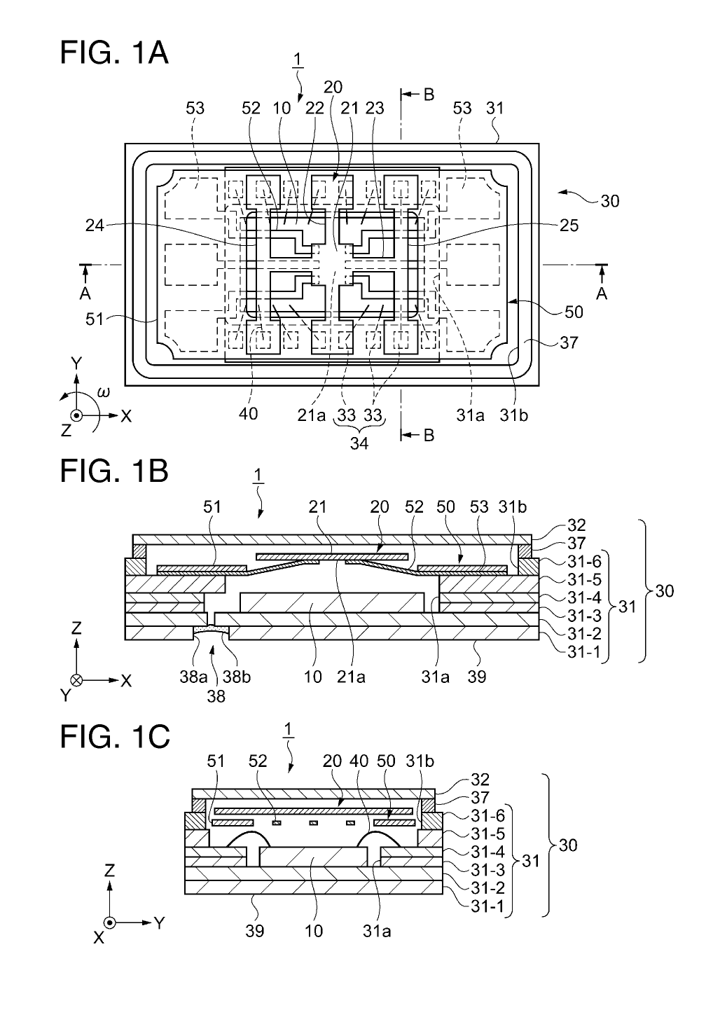

FIGS. 1A to 1C are schematic plan sectional views showing the schematic configuration of a physical quantity sensor in a first embodiment. FIG. 1A is a schematic plan view of the physical quantity sensor overlooked from a lid side, FIG. 1B is a schematic sectional view taken along line A-A in FIG. 1A, and FIG. 1C is a schematic sectional view taken along line B-B in FIG. 1A.

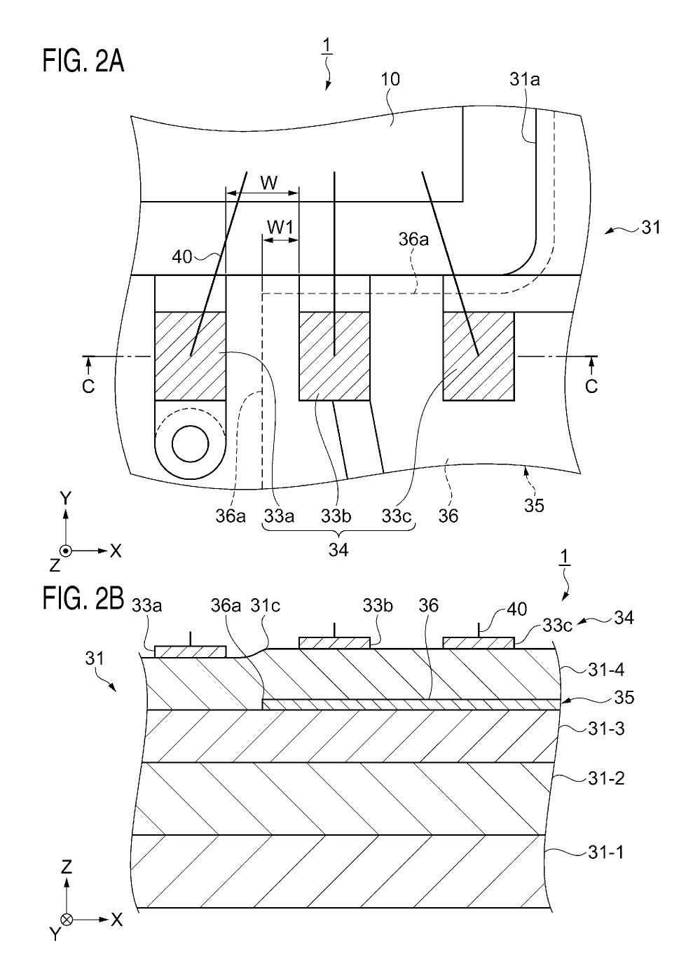

FIGS. 2A and 2B are main part enlarged schematic diagrams of FIGS. 1A to 1C. FIG. 2A is a schematic plan view and FIG. 2B is a schematic sectional view taken along line C-C in FIG. 2A.

Note that, in schematic plan views referred to below, for convenience of explanation, a part of components such as a lid are not shown. In schematic diagrams referred to below, to facilitate understanding, dimension ratios of the components are set different from actual dimension ratios. An X axis, a Y axis, and a Z axis in the figures are coordinate axes orthogonal to one another.

As shown in FIGS. 1A to 1C and FIGS. 2A and 2B, a physical quantity sensor 1 includes an IC chip 10 functioning as an electronic element, a sensor element 20 configured to detect a physical quantity (in this explanation, angular velocity) represented by, for example, angular velocity, acceleration, and pressure, and a package 30 including a package base 31 functioning as a laminated substrate mounted with the IC chip 10 and the sensor element 20.

The package 30 includes the package base 31 substantially rectangular in a plane shape and having a recess and a flat lid 32 substantially rectangular in a plane shape that covers the recess of the package base 31. The package 30 is formed in a substantially rectangular parallelepiped shape.

As the package base 31, a ceramic insulative material such as an aluminum oxide sintered body, a mullite sintered body, an aluminum nitride sintered body, a silicon carbide sintered body, or a glass ceramic sintered body obtained by molding a ceramic green sheet, laminating the ceramic green sheet as a plurality of insulating layers, and baking the insulating layers. Note that, in this embodiment, six insulating layers (31-1 to 31-6) are laminated in this order from a bottom side (a-Z side).

The package base 31 is molded as appropriate to, for example, provide opening portions having a substantially rectangular shape in plan view in the insulating layers (31-3 to 31-6). Consequently, the package base 31 includes a housing recess 31a located substantially in the center of the package base 31 and configured to house the IC chip 10 and a housing recess 31b located above (a+Z side of) the housing recess 31a and configured to house the sensor element 20.

As the lid 32 that covers the housing recess 31a and the housing recess 31b of the package base 31, a material same as the material of the package base 31 or metal such as kovar or 42 alloy is used.

The IC chip 10 includes a driving circuit configured to drive the sensor element 20 and a detection circuit configured to detect a physical quantity detection operation of the sensor element 20 explained below. The IC chip 10 is fixed to the bottom surface of the housing recess 31a of the package base 31 by a not-shown adhesive or the like.

In the IC chip 10, a not-shown plurality of (sixteen) connection terminals are mechanically and electrically connected to, via a bonding wire 40, a plurality of (sixteen) bonding pads 33 of a first wiring layer 34 provided between the insulating layer 31-4 and the insulating layer 31-5 of the package base 31. Note that, as the bonding wire 40, a wire rod of, for example, Au (gold), Cu (copper), or Al (aluminum) is used.

As shown in FIGS. 2A and 2B, the first wiring layer 34 including bonding pads (hatched portions in FIG. 2A; for convenience, respectively represented as 33a, 33b, and 33c) of the package base 31 overlaps a second wiring layer 35 in plan view.

The insulating layer 31-4 is provided between the first wiring layer 34 and the second wiring layer 35. The insulating layer 31-3 is laminated right under (on the −Z side of) the second wiring layer 35.

A contour 36a of a wiring pattern 36 (the second wiring layer 35) provided on the second wiring layer 35 is arranged in a position not overlapping the bonding pads 33a, 33b, and 33c of the first wiring layer 34 in plan view.

A part of the contour 36a of the wiring pattern 36 provided on the second wiring layer 35 is arranged substantially in the middle (W1=W/2 or W1≈W/2) between the bonding pads 33a and 33b adjacent to each other in plan view.

Consequently, as shown in FIG. 2B, in the physical quantity sensor 1, a level difference 31c caused by the rise of the insulating layer 31-4 due to the thickness of the wiring pattern 36 (the second wiring layer 35) does not hang over (overlap) the bonding pads 33a, 33b, and 33c.

As a result, in the physical quantity sensor 1, it is possible to secure flatness of the bonding pads 33a, 33b, and 33c.

Therefore, in the physical quantity sensor 1, bondability of the bonding wire 40 to the bonding pads 33a, 33b, and 33c is improved. It is possible to surely connect (fix) the bonding wire 40 to the bonding pads 33a, 33b, and 33c. Consequently, in the physical quantity sensor 1, it is possible to improve reliability of mechanical and electrical connection of the IC chip 10 and the bonding pads 33a, 33b, and 33c by the bonding wire 40 than the configuration in the past explained below.

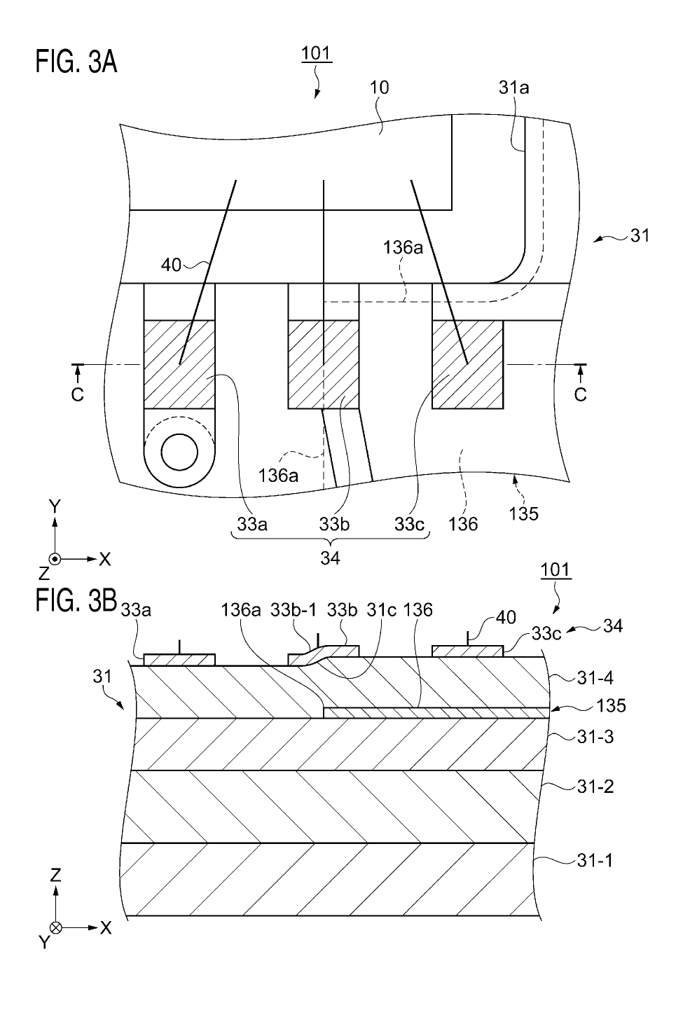

FIGS. 3A and 3B are schematic diagrams showing an example in which the configuration in the past is applied to the physical quantity sensor and a state in which bonding pads of a first wiring layer and a contour of a wiring pattern on a second wiring layer overlap in plan view. FIG. 3A is a schematic plan view and FIG. 3B is a schematic sectional view taken along line C-C in FIG. 3A.

As shown in FIGS. 3A and 3B, in a physical quantity sensor 101 having the configuration in the past, the bonding pad 33b and a contour 136a of a wiring pattern 136 on a second wiring layer 135 (of the second wiring layer 135) overlap in plan view. Therefore, the level difference 31c caused by the rise of the insulating layer 31-4 due to the thickness of the wiring pattern 136 (the second wiring layer 135) hangs over (overlaps) the bonding pad 33b.

Consequently, in the physical quantity sensor 101 having the configuration in the past, since a level difference 33b-1 occurs in the bonding pad 33b, flatness of the bonding pad 33b is spoiled.

As a result, bondability of the bonding wire 40 by, for example, ultrasonic bonding in the bonding pad 33b is deteriorated. Therefore, a connection failure such as non-connection or connection strength insufficiency of the bonding wire 40 occurs.

Consequently, in the physical quantity sensor 101 having the configuration in the past, it is likely that reliability of mechanical and electrical connection of the IC chip 10 and the bonding pad 33b by the bonding wire 40 decreases.

Note that, although not shown in the figures, in the physical quantity sensor 1, the remaining bonding pads 33 are also configured not to overlap the contour (36a, etc.) of the wiring pattern (36, etc.) on the second wiring layer 35.

The physical quantity sensor 1 also includes wiring layers between the insulating layer 31-6 and the insulating layer 31-5, between the insulating layer 31-3 and the insulating layer 31-2, between the insulating layer 31-2 and the insulating layer 31-1, and on the surface on the −Z side of the insulating layer 31-1, and the like. However, for convenience of explanation, the wiring layers are not shown in the figures.

The wiring layer such as the first wiring layer 34 or the second wiring layer 35 of the package base 31 is formed by a metal film obtained by laminating, with a plating method or the like, films of Ni (nickel), Au (gold), or the like on a metalized layer. The metalized layer is formed by, after printing (applying), using, for example, a screen printing method, metal paste obtained by adding and mixing an organic binder and a solvent in metal powder of, for example, W (tungsten) or Mo (molybdenum) and then heating the metal paste.

Note that the wiring layers are connected by a conduction via (a conduction electrode in which metal or a conductive material is filled in a through-hole) or a castellation (a conduction electrode having a semi-through-hole shape provided on an end face of the insulating layer).

Referring back to FIGS. 1A and 1B, the sensor element 20 configured to detect angular velocity as a physical quantity is formed using quartz, which is a piezoelectric material, as a main material. The quartz has an X axis called electrical axis, a Y axis called a mechanical axis, and a Z axis called optical axis. It is assumed that the axes (the X axis, the Y axis, and the Z axis) of the quartz and the coordinate axes (the X axis, the Y axis, and the Z axis) of the figures respectively coincide with each other.

The sensor element 20 is cut out from, for example, a gemstone (Lambert) of quartz along a plane (an XY plane) defined by the X axis and the Y axis orthogonal to each other and is machined to be flat. The sensor element 20 has predetermined thickness in the Z-axis direction orthogonal to the plane. Note that the predetermined thickness is set as appropriate according to an oscillation frequency (a resonance frequency), an external size, workability, and the like.

The sensor element 20 is formed by etching (wet etching or dry etching) using a photolithography technique. Note that a plurality of the sensor elements 20 can be cut out from one quartz wafer.

The sensor element 20 has a configuration called double T type because of the shape thereof.

The sensor element 20 includes a substantially rectangular base 21 located in the center portion of the sensor element 20, a pair of vibrating arms for detection 22 extended from the base 21 along the Y axis, a pair of coupling arms 23 extended from the base 21 along the X axis to be orthogonal to the vibrating arms for detection 22, and pairs of vibrating arms for driving 24 and 25 extended from the distal end sides of the coupling arms 23 along the Y axis.

In the sensor element 20, not-shown detection electrodes are formed in the pair of vibrating arms for detection 22. Not-shown driving electrodes are formed in the pairs of vibrating arms for driving 24 and 25.

In the sensor element 20, the pair of vibrating arms for detection 22 configures a detection vibrating system for detecting angular velocity. The pair of coupling arms 23 and the pairs of the vibrating arms for driving 24 and 25 configure a driving vibrating system for driving the sensor element 20.

Not-shown six connection electrodes drawn out from the detection electrodes and the driving electrodes are provided on a principal plane (a surface on the −Z side orthogonal to the Z axis) 21a of the base 21 of the sensor element 20.

The sensor element 20 is supported by a substantially frame-like sensor substrate 50 having an opening in the center fixed to the bottom surface (a surface on the lid 32 side of the insulating layer 31-5) of the housing recess 31b of the package base 31.

The sensor substrate 50 includes a substrate main body 51 made of resin such as polyimide and a tab tape 52 made of a metal foil of Cu (copper) or the like laminated on the bottom surface side of the housing recess 31b in the substrate main body 51.

On the sensor substrate 50, a plurality of (six) the belt-like tab tapes 52 bent obliquely upward toward the center are extended from an edge of an opening located above (on the lid 32 side of) the IC chip 10.

The distal end of the tab tape 52 is electrically connected to, via a not-shown joining member such as a bump, a connection electrode provided on the principal plane 21a of the base 21 of the sensor element 20.

Consequently, the sensor element 20 is supported horizontally (in parallel to the XY plane) by the sensor substrate 50.

Three terminal electrodes 53 of the sensor substrate 50 connected to the tab tape 52 and arranged at each of both ends in the X-axis direction of the base main body 51 are connected to a not-shown wiring layer on the insulating layer 31-5 on the bottom surface of the housing recess 31b using a conductive adhesive or the like. The terminal electrodes 53 are electrically connected to the IC chip 10 through the conduction via, the bonding pads 33 of the first wiring layer 34, the bonding wire 40, and the like. Consequently, the sensor element 20 is electrically connected to the IC chip 10.

In the sensor element 20, angular velocity ω is applied around the Z axis in a state in which the pairs of vibrating arms for driving 24 and 25 is flexurally vibrating at a predetermined resonance frequency in the X-axis direction. Consequently, the pair of vibrating arms for detection 22 is excited by a Coriolis force generated in the Y-axis direction and flexurally vibrates in the X-axis direction.

The detection electrodes formed in the pair of vibrating arms for detection 22 detect distortion of the quartz caused by the flexural vibration as an electric signal. Consequently, the sensor element 20 can calculate the angular velocity ω around the Z axis.

In the physical quantity sensor 1, in a state in which the sensor element 20 is supported by the sensor substrate 50, the housing recess 31b of the package base 31 is covered by the lid 32. The package base 31 and the lid 32 are hermetically joined by a joining member 37 such as a seal ring, low-melting glass, or an adhesive.

In the package base 31, a sealing section 38 for hermetically sealing the inside of the package 30 is provided in the bottom.

The sealing section 38 includes a stepped through-hole 38a formed in the bottom of the package base 31 and having a hole diameter on an outer bottom surface (a bottom surface on the outer side) 39 side (the insulating layer 31-1) larger than a hole diameter on the housing recess 31a side (the insulating layer 31-2) and a sealing material 38b made of an Au (gold)/Ge (germanium) alloy, an Au (gold)/Sn (tin) alloy, or the like.

The package 30 is reversed after the joining of the lid 32. In a vacuum state (a state with a high degree of vacuum) in a vacuum chamber or the like, the sealing material 38b having a spherical shape is poured into the through-hole 38a from the outer bottom surface 39 side in the sealing section 38. After a laser beam or an electron beam is irradiated on the sealing material 38b to heat and melt the sealing material 38b in the sealing section 38, the through-hole 38a is closed by solidifying the sealing material 38b to hermetically seal the inside of the package 30 in the vacuum state.

Electric power and an input signal are supplied to the physical quantity sensor 1 from the outside via a not-shown external terminal provided on the outer bottom surface 39. The sensor element 20 flexurally vibrates with a driving signal supplied from the IC chip 10. Consequently, the physical quantity sensor 1 detects the angular velocity ω applied around the Z axis and outputs a detection result of the angular velocity ω from the external terminal as an output signal.

As explained above, in the physical quantity sensor 1 in the first embodiment, the contour 36a of the wiring pattern 36 provided on the second wiring layer 35 of the package base 31 is arranged in a position not overlapping the bonding pads 33 (including 33a, 33b, and 33c, the same applies blow) of the first wiring layer 34 in plan view. Therefore, in the bonding pads 33, a level difference (e.g., the level difference 33b-1 shown in FIG. 3B) due to the thickness of the wiring pattern 36 provided on the second wiring layer 35 does not occur.

Consequently, in the physical quantity sensor 1, flatness of the bonding pads 33 is secured. Therefore, bondability of the bonding wire 40 to the bonding pads 33 is improved. It is possible to surely connect (fix) the bonding wire 40 to the bonding pads 33.

As a result, the physical quantity sensor 1 can improve reliability of mechanical and electrical connection of the IC chip 10 and the bonding pads 33 by the bonding wire 40.

In the physical quantity sensor 1, a part of the contour 36a of the wiring pattern 36 provided on the second wiring layer 35 is arranged substantially in the middle between the bonding pads 33 in plan view (specifically, between the bonding pad 33a and the bonding pad 33b adjacent to each other in plan view). Therefore, even if fluctuation in positions occurs, the bonding pads 33a and 33b on both sides of the contour 36a less easily overlap the contour 36a of the wiring pattern 36 and the level difference less easily occurs.

Consequently, the physical quantity sensor 1 can improve the bondability of the bonding wire 40 to the bonding pads 33 while expanding a tolerance of fluctuation in a manufacturing process for the package base 31 (e.g., deviation of laminating positions of the insulating layers 31-3 and 31-4 and deviation of forming positions of the bonding pads 33 of the first wiring layer 34 and the wiring pattern 36 on the second wiring layer 35).

In the physical quantity sensor 1, the insulating layers (31-1 to 31-6) of the package base 31 include the ceramic (ceramics) material. Therefore, for example, the physical quantity sensor 1 is excellent in insulation properties between the wiring layers such as the first wiring layer 34 and the second wiring layer 35. A laminated state of the insulating layers before baking is clayish and soft.

Consequently, in the physical quantity sensor 1, the insulating layer 31-4 is partially raised by the thickness of the wiring pattern 36 on the second wiring layer 35 of the package base 31 and the level difference 31c tends to occur in the first wiring layer 34. Therefore, it is possible to more markedly achieve the effect (the improvement of the bondability by the securing of the flatness of the bonding pads 33).

In the physical quantity sensor 1, the electronic element is the IC chip 10. Therefore, reliability of mechanical and electrical connection of the IC chip 10 and the bonding pad 33 is improved. It is possible to surely actuate the IC chip 10 having the various functions (e.g., the driving circuit configured to drive the sensor element 20 and the detection circuit configured to detect angular velocity as a physical quantity via the sensor element 20).

The physical quantity sensor 1 functioning as the electronic device includes the sensor element 20 configured to detect angular velocity as a physical quantity. The sensor element 20 and the IC chip 10 are electrically connected and function as a physical quantity sensor. Therefor, it is possible to provide the physical quantity sensor excellent in reliability.

Note that, in the embodiment, the main material of the sensor element 20 is quartz. However, the main material of the sensor element 20 is not limited to this and may be a piezoelectric body such as LiTaO₃ (lithium tantalate), Li₂B₄O₇ (lithium tetraborate), LiNbO₃ (lithium niobate), PZT (lead zirconate titanate), ZnO (zinc oxide), or AlN (aluminum nitride) or a semiconductor such as Si (silicon).

As the sensor element 20, besides the double T type, sensor elements of various types such as a bipod tuning fork, a tripod turning fork, an H-type tuning fork, a comb teeth type, an orthogonal type, and a prism type can be used.

The sensor element 20 may be a type other than the vibration type.

A driving method and a detecting method for vibration of the sensor element 20 may be a method by an electrostatic type that makes use of a Coulomb force, a Lorentz type that makes use of a magnetic force, and the like beside the method by the piezoelectric type that makes use of the piezoelectric effect of the piezoelectric body.

The detection axis (the sensing axis) of the sensor element 20 may be axes (e.g., the X axis and the Y axis) parallel to the principal plane 21a of the sensor element 20 besides the axis (the Z axis) orthogonal to the principal plane 21a of the sensor element 20.

In the embodiment, the sensor element 20 configured to detect angular velocity is explained as an example of the sensor element. However, the sensor element is not limited to this and may be, for example, an acceleration sensing element that reacts to acceleration, a pressure sensing element that reacts to pressure, or a weight sensing element that reacts to weight.

Consequently, the electronic device is not limited to the physical quantity sensor 1 (also referred to as gyro sensor) in the embodiment configured to detect angular velocity and may be, for example, an acceleration sensor including the acceleration sensing element as the sensor element, a pressure sensor including the pressure sensing element as the sensor element, or a weight sensor including the weight sensing element as the sensor element.

The electronic device may be a piezoelectric oscillator including a piezoelectric vibrating piece (a piezoelectric transducer) instead of the sensor element.

### Second Embodiment

An electronic apparatus including the electronic device explained above is explained.

The electronic devices such as the physical quantity sensor 1 (the gyro sensor), the acceleration sensor, the pressure sensor, the weight sensor, and the piezoelectric oscillator can be suitably used as a sensor device including a sensing function and a timing device, which generates a reference clock, in electronic apparatuses such as a digital still camera, a video camera, a pointing device, a game controller, a cellular phone, and a head-mounted display. In all the cases, it is possible to provide the electronic device excellent in reliability that reflects the effects explained in the embodiments.

An example of the electronic apparatus is explained below.

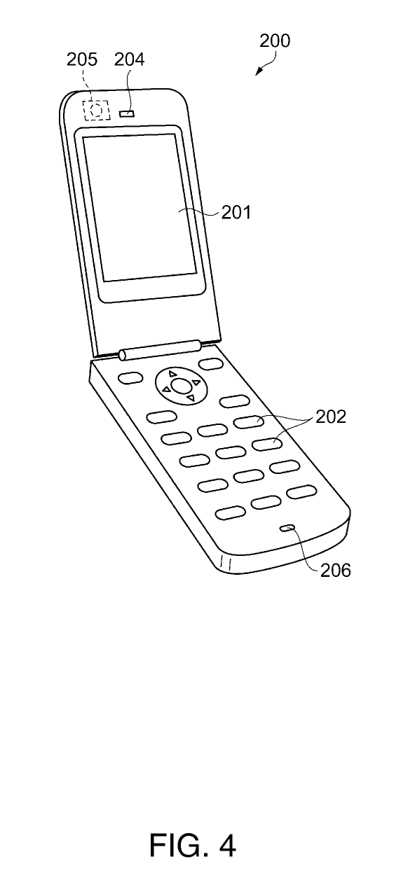

FIG. 4 is a perspective view showing a cellular phone as an example of the electronic apparatus in a second embodiment.

As shown in FIG. 4, a cellular phone 200 includes a plurality of operation buttons 202, an ear piece 204, and a mouth piece 206. A display section 201 is arranged between the operation buttons 202 and the ear piece 204. A small camera 205 is incorporated on the rear side of the ear piece 204.

In such a cellular phone 200, the physical quantity sensor 1 is incorporated. Consequently, the cellular phone 200 can display excellent performance. For example, it is possible to correct a camera shake during photographing by the small camera 205 while realizing a reduction in size.

### Third Embodiment

A moving object including the electronic device explained above is explained.

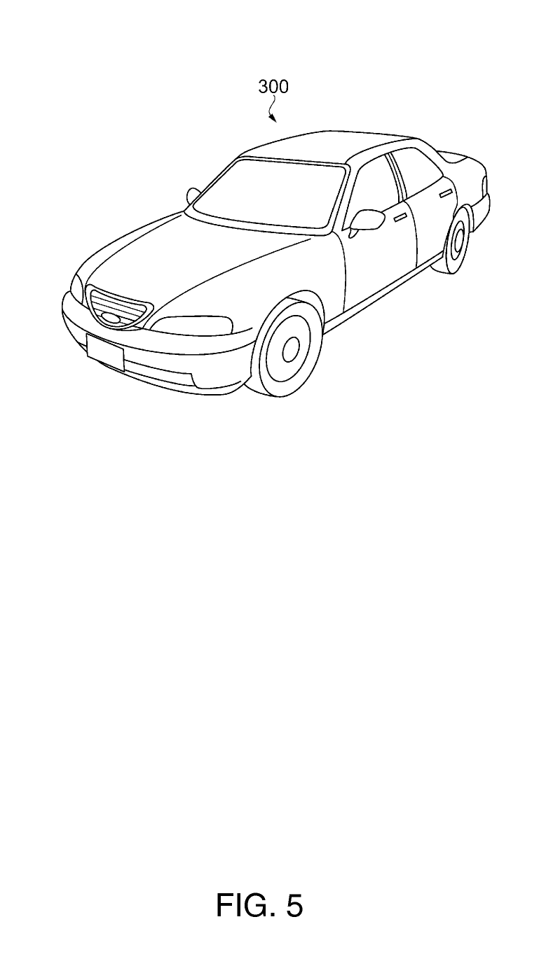

FIG. 5 is a schematic perspective view showing an automobile as an example of the moving object in a third embodiment.

In an automobile 300 shown in FIG. 5, the physical quantity sensor 1 functioning as the electronic device is used as a posture detection sensor of a navigation device or a posture control device mounted on the automobile 300.

According to the third embodiment, the automobile 300 includes the physical quantity sensor 1. Therefore, the effects explained above in the embodiments are reflected, reliability is improved, and excellent performance can be displayed.

In the automobile 300, a piezoelectric oscillator functioning as the electronic device can be suitably used as, for example, a timing device configured to generate a reference clock for various electronic control devices (e.g., an electronically controlled fuel injection device, an electronically controlled ABS device, and an electronically controlled constant speed traveling device) mounted on the automobile 300. Therefore, reliability is improved and excellent performance can be displayed.

The electronic devices such as the physical quantity sensor 1 and the piezoelectric oscillator can be suitably used as a posture detection sensor and a timing device for not only the automobile 300 but also mobile bodies such as a self-propelled robot, a self-propelled conveying apparatus, a train, a ship, an airplane, and an artificial satellite. In all the cases, it is possible to provide the moving object excellent in reliability that reflects the effects explained in the embodiments.

The electronic device, the electronic apparatus, and the moving object according to the invention are explained on the basis of the embodiments shown in the figures. However, the invention is not limited to this. The components can be replaced with arbitrary components having the same functions. Other arbitrary components may be added to the invention.

The embodiments are explained in detail above. However, it goes without saying that various modifications are possible without substantially departing from the new matters and the effects of the invention. Therefore, all such modifications are included in the scope of the invention. For example, the number of laminated layers of the insulating layers is not limited to six and may be one to five or may be seven or more.

The entire disclosure of Japanese Patent Application No. 2013-032941, filed Feb. 22, 2013 is expressly incorporated by reference herein.

What is claimed is:

1. An electronic device comprising:
an electronic element; and
a laminated substrate mounted with the electronic element, wherein
the laminated substrate includes:
a first wiring layer provided with at least one bonding pad connected to the electronic element via a bonding wire;
a second wiring layer overlapping the first wiring layer in plan view; and
an insulating layer provided between the first wiring layer and the second wiring layer, and
a contour of the second wiring layer is arranged in a position not overlapping the bonding pad in plan view.

2. The electronic device according to claim 1, wherein
at least a plurality of the bonding pads are provided, and
a part of the contour of the second wiring layer is arranged substantially in a middle between the bonding pads adjacent to each other in plan view.

3. The electronic device according to claim 1, wherein the insulating layer includes a ceramic material.

4. The electronic device according to claim 1, wherein the electronic element is an IC chip.

5. The electronic device according to claim 4, further comprising a sensor element configured to detect a physical quantity, wherein
the sensor element and the IC chip are electrically connected and function as a physical quantity sensor.

6. The electronic device according to claim 1, wherein all of the bonding pads provided on the first wiring layer are arranged in positions not overlapping the contour of the second wiring layer in plan view.

7. A package comprising:
a first wiring layer provided with at least one bonding pad;
a second wiring layer overlapping the first wiring layer in plan view; and
an insulating layer provided between the first wiring layer and the second wiring layer, wherein
a contour of the second wiring layer is arranged in a position not overlapping the bonding pad in plan view.

8. The package according to claim 7, wherein
at least a plurality of the bonding pads are provided, and
a part of the contour of the second wiring layer is arranged substantially in a middle between the bonding pads adjacent to each other in plan view.

9. The package according to claim 7, wherein the insulating layer includes a ceramic material.

10. The package according to claim 7, wherein all of the bonding pads provided on the first wiring layer are arranged in positions not overlapping the contour of the second wiring layer in plan view.

11. An electronic apparatus comprising the electronic device according to claim 1.

12. A moving object comprising the electronic device according to claim 1.

13. An electronic apparatus comprising the package according to claim 7.

14. A moving object comprising the package according to claim 7.
